(19) United States
(12) Patent Application Publication
(10) Pub. No.: US 2010/0123078 A1
(43) Pub. Date: May 20, 2010

(54) METHOD AND DEVICE FOR SCANNING

(76) Inventor: Robert Guinta, Woodcliff Lake, NJ (US)

Correspondence Address: Hershkovitz & Associates, LLC, 2845 Duke Street, Alexandria, VA, 22314, US

(21) Appl. No.: 12/621,236

(22) Filed: Nov. 18, 2009

Related U.S. Application Data
(60) Provisional application No. 61/115,858, filed on Nov. 18, 2008.

(51) Int. Cl. G02B 26/10; H01L 31/00

(52) U.S. Cl. 250/334

(57) ABSTRACT

A thermal scanning and imaging system contained within a closed area for a patient to enter and have a thermal scan completed to generate a thermal image of the patient from the thermal scan.

### BACKGROUND OF THE INVENTION

1. Field of the Invention

The present invention relates to scanning and, more particularly, to thermal scanning of humans to detect anomalies within a human's heat pattern that may be clinically significant.

2. Description of the Prior Art

Numerous types of testing exist for determining abnormalities within the human body. Many types of tests do are not diagnostic but can reveal significant information. Thermal Imaging, mammography magnetic resonance imaging (MRI) and ultrasounds are tests are not diagnostic tests; however, they do provide information regarding abnormalities within a patient's body. Thermal Imaging is an objective test measuring skin surface temperature to a very sensitive and accurate degree reflecting changes in physiological and metabolic activity within the underlying tissue area.

Computerized thermal imaging (CTI) is a non-invasive technique that measures changes in skin surface temperature and quantifies these changes. A visual image can be generated illustrating the relative temperatures of various areas of a patient's skin. Thermal imaging is typically accomplished using an infrared scanning device to sense the amount of the surface of a patient's skin. A visual image uses colors to indicate the amount of infrared radiation detected by the infrared scanning device. Abnormalities in the heat pattern of a patient's skin can be detected. Hot and/or cool spots can be detected in relation to the immediately surrounding areas. Thermal abnormalities can also be detected employing the concept of thermal symmetry in the body. Tumors will emit more heat than surrounding tissue and detecting these abnormalities can provide indications of risk factors.

Prior art techniques for CTI employ heat sensitive cameras designed to detect heat given off by an individual and construct images of the individual's heat patterns. These images differentiate between normal and abnormal heat patterns within an individual. In a typical prior art CTI examinations, individuals may be positioned on special examination beds and positioned with portions of their anatomy (such as breasts) suspended within specialized openings in the bed to allow correct positioning of the heat sensitive camera.

One type of CTI system employs mirrors that deflect infrared waves from a patient's breast to a camera below. Another existing CTI system requires thermal images be taken be a certified clinical thermographer that is trained to use a specialized camera.

From the foregoing discussion, it should be readily apparent that a need remains within the art for a thermal scanning and imaging system that is convenient for the patient, allows the patient to remain in a comfortable position, can be reviewed in a cost effective manner by clinicians and does not require specialized personal to operate the scanning system to obtain a scan of a patient.

### SUMMARY OF THE INVENTION

The embodiments disclosed herein address the shortcomings contained within the prior art by providing a method and system for acquiring thermal images in a simple and effective manner. Embodiments also discuss methods to have thermal images analyzed.

### BRIEF DESCRIPTION OF THE DRAWINGS

FIG. 1 is a diagram illustrating a thermal imaging system;

FIG. 2A is a diagram for a frontal view of a patient sitting on a chair to provide a predetermined position for scanning;

FIG. 2b is a side view of FIG. 2A illustrating the relation to the patient in a predetermined position to a thermal scanning device;

FIG. 3 illustrates an overhead view of the patient;

FIGS. 4A-4F illustrate thermal patterns that can be recognized in a thermal image as factors of concern;

FIGS. 5A-5L illustrates another set of patterns that can be recognized in thermal image and also used as factors of concern;

FIG. 6 is an illustration of cancer occurrence rates in the breast;

FIGS. 7A and 7B illustrate a analysis techniques applied to the frontal position;

FIGS. 8A and 8B illustrate a posterior view of the human body and analysis techniques;

FIG. 9 is a chart used to list factors found from analysis similar to that discussed in relation to FIGS. 7A and 7B;

FIG. 10 is a chart used to list factors found from analysis similar to that discussed in relation to FIGS. 8A and 8B;

FIG. 11 is a series of images reflecting the thermal images taken in a sitting position; and

FIG. 12 is a series of images reflecting the thermal image taken in a standing position.

### DETAILED DESCRIPTION OF THE INVENTION

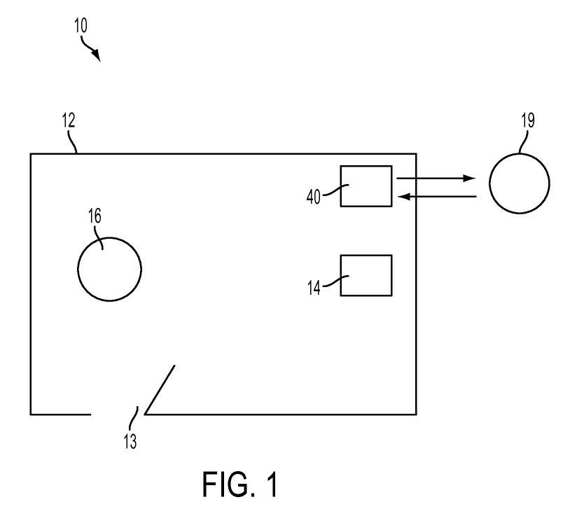

Referring to FIG. 1, system 10 provides the necessary items for creating a thermal image of a patient. An enclosed area 12 provides privacy for the patient while a scan is completed. Inside the enclosed area 12, a scanning device 14 is arranged to scan a patient. In an embodiment, no assistance from any additional person is required for the patient to have the scan completed. The enclosed area 12 contains a positioning arrangement 16 for positioning the patient while a scan is being performed.

In an embodiment, system 10 is interfaced with a server 19 as shown by the bi-directional arrows in FIG. 1. This interface can employ any conventional communication techniques. Thermal images taken by system 10 can be placed on server 19 for later analysis.

The enclosed area 12 can be an automated compartment akin to a kiosk that creates a thermal scan of a patient that can be stored and transmitted. Enclosed area 12 includes entrance 13 which enables the patient to enter or leave enclosed area 12. After entry into enclosed area 12, the entrance 13 can be closed providing privacy for patient within enclosed area 12. Enclosed area 12 can be equipped with interface equipment that can be initiated by the patient, or be equipped to initiate automatically once a predetermined situation is encountered by enclosed area 12. Elements can be placed within enclosed area 12 to initiate an audio or visual mechanism to present instructions. A patient activated mechanism could be employed that includes the closing of entrance 13, or sitting in a chair inside enclosed area 12. Once either initiated automatically or by the patient, the patient receives instructions to be followed to have the scan completed. Processing elements associated with system 10 can initiate audio, visual, audio/visual or multimedia communication with the patient to proceed with the scan. The stored thermal scans can then be examined by a clinician present at that time, stored and/transmitted for clinician review at a later time, or stored and transmitted for clinician review remotely from enclosed area 12.

In another embodiment, a business construct is created whereby clinicians can be associated with the organization that owns and/or operates system 10. Thermal scans and images can be reviewed by a remotely based doctor or other clinician without any interaction between the patient and another person. Many business arrangements can be made clinicians to provide reviews of scans and images generated by system 10. In such an embodiment, scans and images can be reviewed under a predetermined pricing arrangement no direct interaction between the patient and a clinician/doctor needs to take place. Clinicians that are skilled in thermal imaging can receive downloads of stored thermal scans/images and review them at their convenience, such as at their home in the evening or during the day at work. The scans and images generated by system 10 can be used to determine if further testing is desirable, or used in conjunction with other imaging tests such as mammograms. In such embodiments, patients can enter enclosed area 12 at their convenience and have a scan completed. The thermal scans/images can be reviewed a later time and remotely. Therefore, the patient does not need to make an appointment but could instead enter enclosed area 12 within an automated system 10 to have a thermal scan performed and a thermal image generated.

In another embodiment, the patient can review the thermal scan be and the thermal image to determine if further review by a clinician would be necessary or desirable. The system 10 can be provided with a mechanism to allow the patient to review the thermal image created'from the scan inside enclosed area 12 or near enclosed area 12. Arrangements can be made to have the thermal image and/or scan data sent to the patient to allow the patient to review the scan and image. The patient could then decide if further involvement with a clinician was desirable. Further arrangements can have a list of clinicians and/or doctors that are available to receive and review thermal scans/images on a predetermined price basis.

In another embodiment, the scan is initiated either manually or atomically and the final thermal image that is created can be made available to the patient for viewing. The patient could decide to transfer the recorded scan to a clinician or retrieve a copy for storage and later viewing. A storage system could be employed to enable later retrieval of stored scans. Electronic transfers or scans could easily be accommodated by conventional communication means such as the internet.

The manner in which the scan is accomplished can be completely automated or have any of various levels of human action required. This human action can be an action on the part of the patient or an action performed by a person controlling system 10. For example, a patient could enter enclosed area 12, and while in a private setting, receive instructions to partially disrobe and sit in a chair. The chair could be positioned such that scanning device 14 would be able to focus on a specific target area of the patient in the chair.

Numerous types of positioning arrangements 16 can be used to position the patient during scanning and this will be readily apparent to those skilled within the art. These positioning arrangements 16 can be seated, standing, or a combination of both.

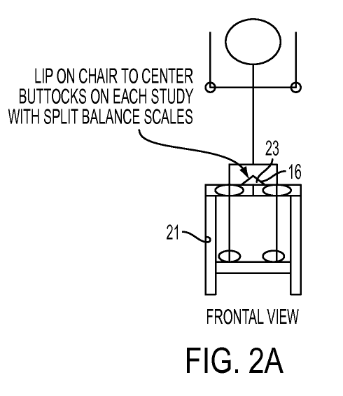

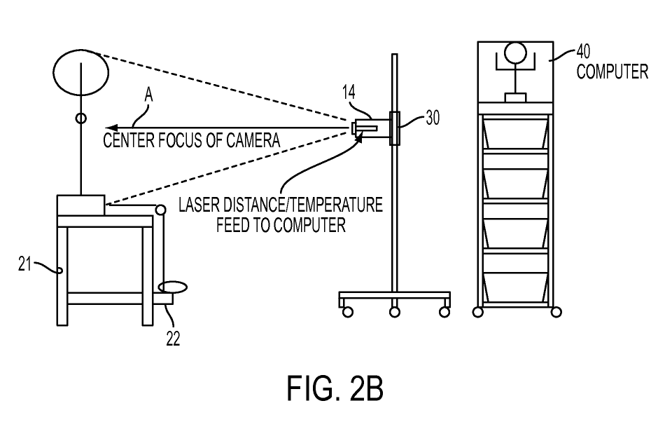

In one particular embodiment, the positioning arrangement 16 seats the patient in a predetermined position allowing the scanning device 14 to automatically scan the patient. Alternative embodiments can have any of various levels of human interaction with the scanning process. Referring to FIG. 2A, the positioning arrangement 16 can be a chair designed to rotate 360° at predetermined intervals allowing the scanning device to perform scans of the patient as the chair is rotated. Devices other than a chair can be used for the positioning arrangement. For example, varying embodiments can employ a rotating platform or marking indicating where the patient should stand for each of the individual predetermined intervals. Various rotational intervals can be employed such as 30°, 45°, 90° intervals or other predetermined intervals. The positioning arrangement 16 can be rotated at these predetermined intervals to allow scanning device 14 to acquire a scan of the patient at each predetermined interval. Thus, in an embodiment having 45° rotational intervals could have 0°, 45°, 90° 135°, 180°, 225°, 270°, and 317° as intervals before returning to 0° is so desired. Similarly, an embodiment having 30° rotational intervals could have 0°, 35°, 60, 90° 120, 150°, 180°, 210°, 240°, and 270° as intervals. The positional arrangement 16 can conceivably use any interval level desired.

A thermal imaging device can be associated with the scanning device. Furthermore, the scanning device itself can be a thermal imaging device that thermally scans the patient. Alternatively, the scanning device can be associated with a thermal imaging device to obtain a thermal image of the patient.

FIG. 2A illustrates a frontal view of a patient sitting in a chair 21 that forms part of the positioning arrangement 16. The chair 21 can have a positioning device 22 to locate the patient in a predetermined position for scanning. Positioning device 22 can include a foot rail to rest the feet of the patient upon. The positioning device 22 can include a lip 23 formed on the chair 21 to center the patient's buttocks on the lip 23 placing the patient in the predetermined position. The position of lip 23 could be used to determine the position of the patient to place the patient into the predetermined position. The chair can adapted to be rotated at predetermined intervals as described above. The scanning device 14 can anticipate the patient being in the predetermine position and have a target area on the patient that is the predetermined focal point for scanning device 14. A fiduciary marker or fiducial point can be placed on the patient in a predetermined area of the patient that is know to system 10 to provide for automatic operation. Alternatively, the predetermine position could be a standing position with placement indicators provided to allow the patient to be aware to stand for each interval.

FIG. 2B shows a side view of FIG. 2A. The patient is shown sitting on chair 21 at the 0° interval for scanning by thermal imaging device 30 (a specific version of scanning device 14). Thermal imaging device 30 can feed temperature readings into a computational element 40. Laser distance can also be fed into computational element 40 by thermal imaging device 30. Here a computational element 40 can be any type of computer, processor or controller. Different embodiments can incorporate the computational element 40 within the thermal scanning device or employ a stand alone computer as the computational element. Thermal scanning device 30 can perform a continuous study of the upper torso using a predetermined number frames per second for a given period of time. For example, differing embodiments could have thermal imaging device 30 perform an upper torso study on the patient by scanning the patient torso area at a rate of 30-50 frames per second for a half minute, full minute or for longer or shorter durations. The frames per second rate and scan time can be varied in accordance with differing embodiments. The thermal scanning device 30 can use a specific area for focusing purposes. For example, an embodiment could place the center of focus on the xiphoid (zyphoid) area of the patient as shown by arrow “A” in FIG. 2B.

Thermal scanning device 30 can be arranged in various embodiments to determine the distance to the patient from the thermal scanning device 30 and send this information to the computational element 40. In another embodiment, the thermal scanning device 30 could be configured to determine the ambient temperature in enclosed area 12 and send that information to the computer. Another embodiment could send distance of thermal scanning device 30 to the patient and/or ambient temperature conditions upon initiating a new study so that this information can be compared with former readings. The completed study could then be compared with a previous study using not only the thermal data determined from the patient by the thermal scanning device 30 but also consider the ambient temperature conditions and distance of the patient from the thermal scanning device 30 as parameters in the comparison.

Embodiments can provide differing resolutions for the thermal scan of a patient. Some embodiments can have the thermal scan arranged with more vertical pixels than horizontal. Other embodiments could employ resolutions currently existing within standard computer display formats. Resolutions can be tailored to the intended positioning of the patient in either a more vertical or a more horizontal position, depending on specific embodiments.

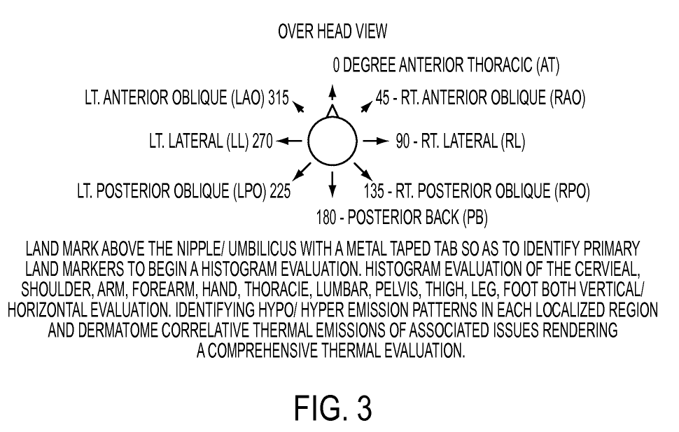

FIG. 3 is an overhead view of various positions the patient could be positioned at in 45° increments. The overhead view in FIG. 3 shows a frontal view as 0° useful for anterior thoracic (AT) analysis and views proceeding clockwise: a 45° view that is useful for right anterior oblique analysis, 90° view that is useful for right lateral analysis, a 135° view that is useful for posterior oblique analysis, a 180° view that is useful for posterior back analysis, a 225° view that is useful for posterior oblique analysis, a 270° view that is useful for left lateral analysis, and a 315° view that is useful for anterior oblique analysis.

Thermal emission patterns that exhibit unusually cold or cool readings on a thermal scan can are represent a decrease in blood supply. These are referred to herein as hypo-emission patterns related. Hypo-emissions can be the result of problems related to nerve irritation or dysfunction and restricted circulation can produce thermo graphic cold patterns. Cold asymmetries (lack of symmetry) usually result from (sympathetic) nerve irritation. Nerve irritation can trigger muscles around the blood vessels to contract, preventing the supply of blood to an effected area.

Thermal patterns that are unusually warm represent an increase in blood supply and local tissue temperature, which can be indicative of inflammation. Also, wounds, blood pooling, nerve malfunction or abnormal blood vessel formations/alterations typically produce heat patterns on a thermal scan. These warm thermal patterns are generally referred to herein as hyper-emission patterns.

In an embodiment, histograms can be formed of one or more areas of a patients' body. A thermal image histogram can be used to get thermal signatures and analyze symmetry. For example, a land mark, or indicia, can be created in the area near the nipple to the patients' breast. The nipple can function as an umbilicus, or center point, and indicia can be formed in close proximity to the nipple. Indicia can be formed by placing metal tabs (either by taping or other means) to identify primary land markers to begin a histogram evaluation. The land marker, or indicia, allows very precise location for analysis purposes. Histogram evaluation can also be performed for the cervical, shoulder, arm, forearm, hand, thoracic, lumber, pelvis, thigh, leg, or foot. The evaluation can be performed in either vertical or horizontal evaluation modes or both.

An embodiment identifies hypo-emissions and hyper-emission by reviewing thermal patterns in each localized region and dermatome correlative thermal emissions of associated issues rendering a comprehensive thermal evolution.

A dermatome is an area of skin whose sensory nerves all come from a single spinal nerve root. Spinal roots come in pairs with one of each of the spinal roots of the pair on each side of the body. A Dermatome is a skin area associated with a pair of roots from the spine. Damage to a spinal nerve (such as compression for example) can create pain elsewhere in the body. A dermatome is thus the area of the body covered sensory nerves that all come from a single spinal nerve root. The body is essentially divided into regions supplied by single spinal nerves. There are eight cervical, twelve thoracic, five lumbar and five sacral spinal nerves. Dermatomes can be viewed as the areas of the human body that are serviced by these spinal nerves.

Land marks (fiducials) can be established in predetermined areas. For example, above the nipple/umbilicus area, a metal tab with adhesive or other connective material can be used as primary land markers to identify an area to begin a histogram evaluation. Histogram evaluation can be performed of the cervical, shoulder, arm forearm, hand, thoracic area, lumber, pelvis, thigh, leg, foot (both vertical/horizontal evaluations) or virtually any [part of the human body. Thermal emission patterns that identify cold or cool area are referred to as hypo-emission patterns. Those areas that identify warm or hot areas are referred to as hyper-emission patterns. These patterns can be localized by region and reviewed for potentially being dermatome correlative thermal emissions that can identify associated issues rendering a comprehensive thermal evaluation.

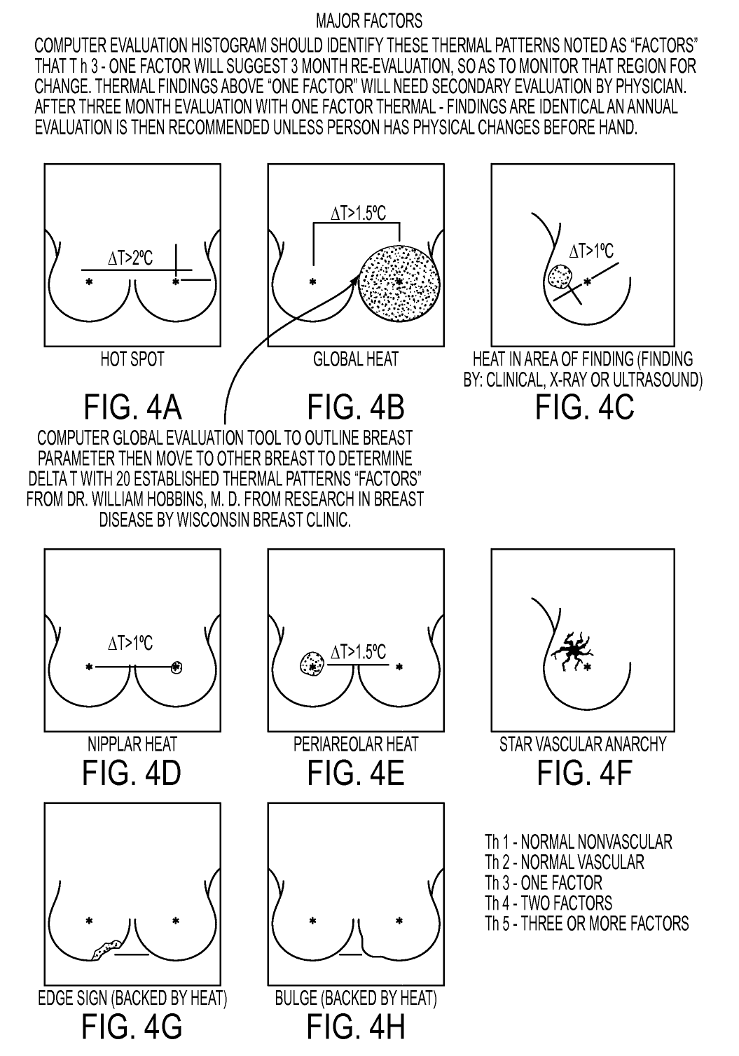

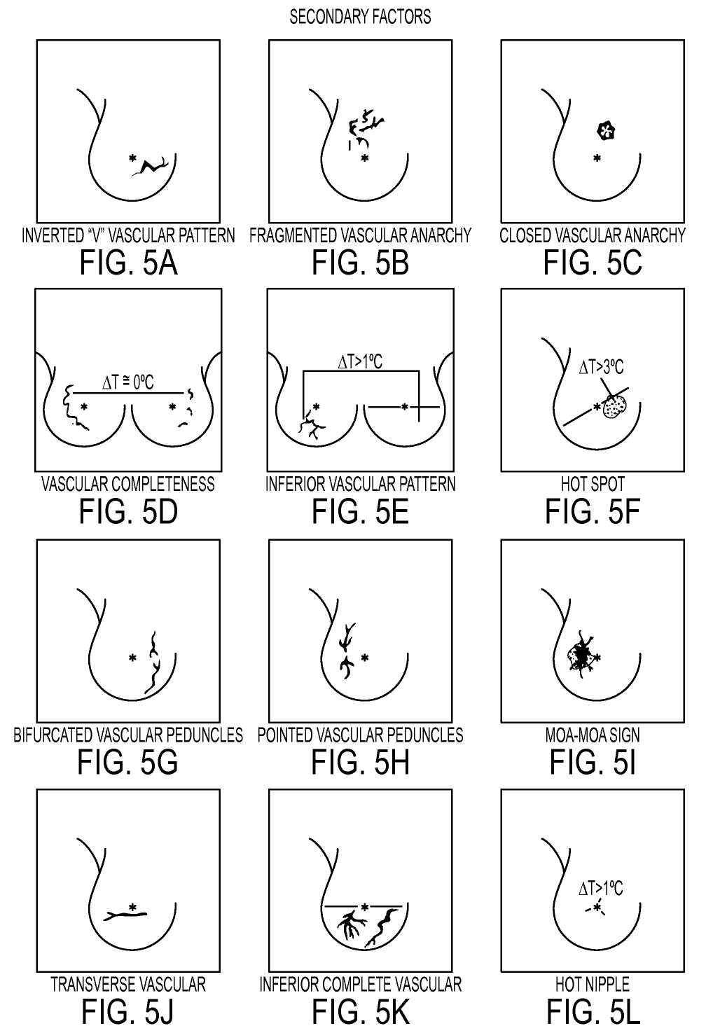

FIGS. 4A-4H illustrate Major Factors that can be used in evaluating a thermal image. FIGS. 5A-5L illustrate secondary factors that can be evaluated in reviewing a thermal image. Other factors can also be reviewed by a computer running algorithms that interpret the thermal image data. Computer evaluation techniques can be applied to these “factors”. For example, a histogram could identify the thermal patterns shown in FIGS. 4A-4H or FIG. 5A-5L as a “factor”. In an embodiment, identification of a single “factor” indicates that at least a reevaluation of the patient will be suggested within a predetermined time period. Reevaluations periods can be from weeks to months, for example three (3) months or three (3) weeks. After a reevaluation is performed, the “factor” previously exhibited can be the initial focus of the reevaluation. If the condition remains the same, the patient can be placed on a regular evaluation schedule, such as once a week, once a month or once a year. This reevaluation period can be altered if physical change in the patient is witnessed. If the patients condition becomes worse, then

In another embodiment, the identification of more than one of the “factors” leads to a termination that a secondary evaluation from a physician or other clinician is needed. The physician or clinician can make a determination if more extensive or even invasive testing should be undertaken. Identification of multiple Major Factors could lead the clinician or patient to seek mammograms, ultrasound, Magnetic resonance Images (MRIs) or other scanning tests to be performed.

In another embodiment, identification of “factors” can be made by computer algorithms being applied to a thermal image using well known digital signal processing (DSP) and digital averaging techniques. These computer algorithms can be within system 10 or the thermal image can be transferred and the algorithms applied at a remote location. System 10 provides embodiments that allow a patient to quickly have a thermal image created or have a thermal image transferred to a clinician or physician for review. Identification of a Major Factor could lead the clinician or patient to seek additional studies regarding the found factor, such as mammograms, ultrasound, X-ray, Magnetic Resonance Images (MRIs) or other scanning tests to be performed.

In another embodiment, system 10 will search the thermal image created from the scan for a list of factors. A grade of 1-5 can be given. Grade 1 indicates normal nonvascular readings; Grade 2 indicates normal vascular readings; grade 3 indicates one factor founds; grade 4 indicates two factors found; and grade 5 indicates three or more factors found. Therefore, grades higher than Grade 2 indicate clinically significant factors.

Computer evaluation tools can be implemented to outline global areas and/or local areas of the patient's body. These evaluation tools can be used to identify areas, such as by placing a virtual geometric figure around the area. The evaluation tool can be a circle or a rectangle. Preset parameters can be applied to the areas outlined by the evaluation tool to determine anomalies. For example, the breast of a female patient can be outlined and compared with a similar outline for the opposite breast for temperature differentials in accordance with numerous parameters.

In performing a mammogram, standard protocol is to take 4 images that include lateral and vertex views of each breast. In performing a mammatherm (thermal image of the breast), standard protocol is to take 5 images that include anterior, lateral and oblique views of the breast. If imaging is to be performed on the same day, the Mammatherm should be performed first due to compression of the breast by the Mammogram, so as not to produce thermal artifacts. Otherwise, Mammograms initially performed need 24 hours before the Mammatherm is performed but not longer than one week from the date of the Mammogram. The purpose here is to establish a level of consistency in significant findings between both imaging systems (Mammography and Mammatherm).

In an embodiment, Mammatherm studies create an initial baseline study then in three months, the patient is recalled to verify consistency in imaging and/or changes in tissue activity. A consideration is that false positive from mammograms can result in biopsies being performed directly from mammogram results. These biopsies may not have been performed if a thermal scan was taken and the thermal image reviewed.

In another embodiment, prior results from mammograms that facilitated biopsies being performed should be differentiated to initial mammogram study. High risk factors noted on a thermal scan/image can be correlated with a sonogram.

Standards by American Academy of clinical Thermology regarding infrared imaging of the breast are as follows:

FIGS. 4A-4H and 5A-5L are examples of factor that can be found in a thermal image by recording thermal scans of each breast and comparing corresponding areas comparisons can be made of corresponding areas. Here, global evaluation tool could be placed around each breast individually and those breast areas examined for temperature readings.

FIG. 4A illustrates a hot spot in a specific area of one breast compared to the opposite breast. If a temperature difference of greater than 2° C. is found in corresponding areas of opposite breasts. Greater or lesser temperature differences can be used for making hot spot comparisons.

FIG. 4B illustrates a global heat in one breast compared to the opposite breast. A temperature difference of greater than 1.5° C. can be found using thermal scans of each breast and comparing the global temperatures of each breast.

FIG. 4C illustrates heat in area of finding, which refers to a heat anomaly within a single breast. Here, a temperature difference of greater than 1° in a single breast is found within the thermal scan.

FIG. 4D illustrates a nipplar heat differential found between opposite nipples. In one breast a temperature difference of greater than 1° C. is found compared to the opposite breast.

FIG. 4E illustrates periarolar (nipple boundary) heat it determined to exist between the opposite breasts. A temperature difference of greater than 1.5° C. if found will be recorded as a “factor”.

FIG. 4F illustrates a thermal pattern that is referred to as a star vascular anarchy that can be found in the thermal scan of a patient.

FIG. 4G is an edge sign found in the breast of a patient illustrating deformation in one of the breasts. The edge sign can be backed by heat as seen on the thermal image or simply exist in the outline of the breast and be seen on a thermal image.

FIG. 4H illustrates a bulge in a specific area of one breast compared to the opposite breast. The bulge can be backed by heat seen on the thermal image or simply exist in the outline of the breast also viewable in thermal image.

The factors shown in FIGS. 5A-5L can be viewed as “factors” also in making a determination of significant anomalies in the thermal image of a patient.

FIG. 5A is a heat pattern for an Inverted V Vascular Pattern. This vascular pattern can be identified in the thermal image due to temperature differences between the Inverted V Vascular Pattern and the surrounding breast area.

FIG. 5B shows a heat pattern for a Fragmented Vascular Anarchy. This vascular pattern can be identified in the thermal image due to temperature differences between the Fragmented Vascular Anarchy and the surrounding breast area.

FIG. 5C illustrates a heat pattern for a Closed Vascular Anarchy. This vascular pattern can be identified in the thermal image due to temperature differences between the Closed Vascular Anarchy and the surrounding breast area.

FIG. 5D is a heat pattern that could occur for Vascular Completeness. This vascular pattern can be identified by virtually no temperature differences exist between opposite vascular areas in the breasts of the patient.

FIG. 5E illustrates a heat pattern for an Inferior Vascular Pattern. This vascular pattern can be identified by a temperature difference of at least 1° C. that exists between corresponding vascular areas of opposite breasts in the patient.

FIG. 5F is a heat pattern indicative of a Hot Spot within a single breast. This pattern can be determined by a temperature variation of at least 3° C. in areas on opposite sides of the nipple on the same breast.

FIG. 5G shows a pattern for Bifurcated Vascular Peduncles. This pattern can be identified in the thermal image due to temperature differences between the surrounding breast tissue and the Bifurcated Vascular Peduncles.

FIG. 5H illustrates a pattern for Pointed Vascular Peduncles. This pattern can be identified in the thermal image due to temperature differences between the surrounding breast tissue and the Pointed Vascular Peduncles.

FIG. 5I is an example of a Moa-Moa Pattern in the breast of a patient. This pattern can be identified in the thermal image due to temperature differences between the surrounding breast tissue and the Moa-Moa Pattern.

FIG. 5J is an example of a Transverse Vascular Pattern. This pattern can be identified in the Thermal image due to temperature differences between the surrounding breast tissue and the Transverse Vascular Pattern that runs from on side of a breast to the opposite side.

FIG. 5K is an example of an Inferior Complete Vascular Pattern. This pattern can be identified in the thermal image due to temperature differences between the Inferior Complete Vascular Pattern and the surrounding breast tissue.

FIG. 5L is a heat pattern indicative of a Hot Nipple. This heat pattern can be determined by a temperature variation of at least 1° C. in the nipple from the areas surrounding nipple itself.

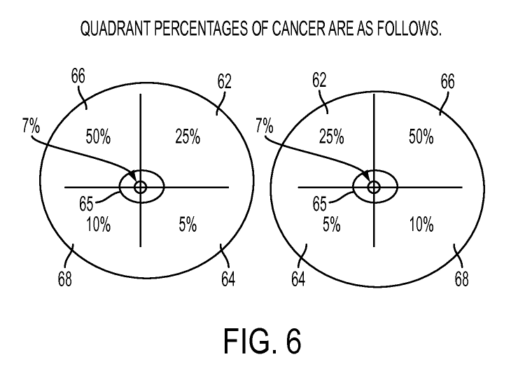

FIG. 6 is an illustration of breast areas and their propensity for cancerous tumors to occur in each area. The inside lower quadrant 64 of each breast has the lowest statistical occurrence rate for carcinomas at 5% of breast tumors. The nipple area 65 has the next lowest occurrence rate at 7% of occurring breast tumors. The outside lower quadrant 68 of the breasts is next lowest at 10%. The outside upper quadrant 66 of the breast has the highest breast cancer occurrence rate at 50%. The second highest occurrence rate for beast carcinomas is the upper inside quadrant 62 having 25% of breast cancers. These numbers do not add up to 100% but do account for 97% of tumors found in breast cancer patients.

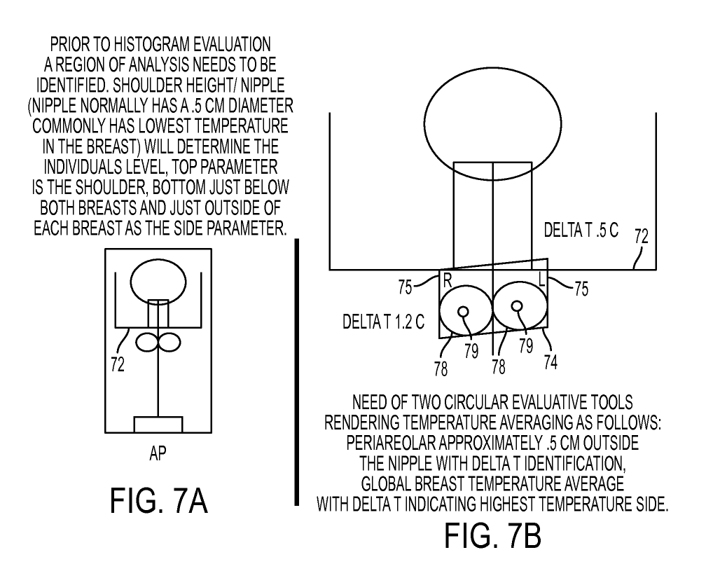

FIGS. 7A and 7B illustrate analysis techniques applied to the frontal position. In an embodiment, prior to histogram evaluation a region of analysis needs to be identified. The shoulder height, nipple location (nipple normally has a 0.5 cm diameter and commonly has the lowest temperature in the breast) can provide area identification for the patient. The top parameter could be the shoulder 72 of the patient, the bottom parameter could be just below both breasts 74 of the patient and the outside of each breast 75 could serve as side parameters. Once areas are identified, analysis of the thermal scan can proceed.

FIG. 7B illustrates evaluation tools being applied to identified area. Here evaluation tool 79 is placed around the nipple area of one breast to take temperature readings of the area of the nipple. Then tool 79 is placed around the nipple area of the opposite breast to take temperature readings. In a similar manner, evaluation tool 78 is placed around the area of one breast to take temperature readings of that breast area. Then tool 78 is placed around the area of the opposite breast to take temperature readings of that breast. The two evaluative tools 78, 79 can render temperature averaging in many different ways. For example, in one manner of temperature averaging, the periaeolar area approximately 0.5 cm outside each nipple can have the temperature of that area identified with a Delta T (change in temperature) from the nipple. Tool 78 can be used to compute the global breast temperature average can. The side with the highest temperature can then be computed. The differences in temperature of the two sides (left and right) can provide clinically significant data.

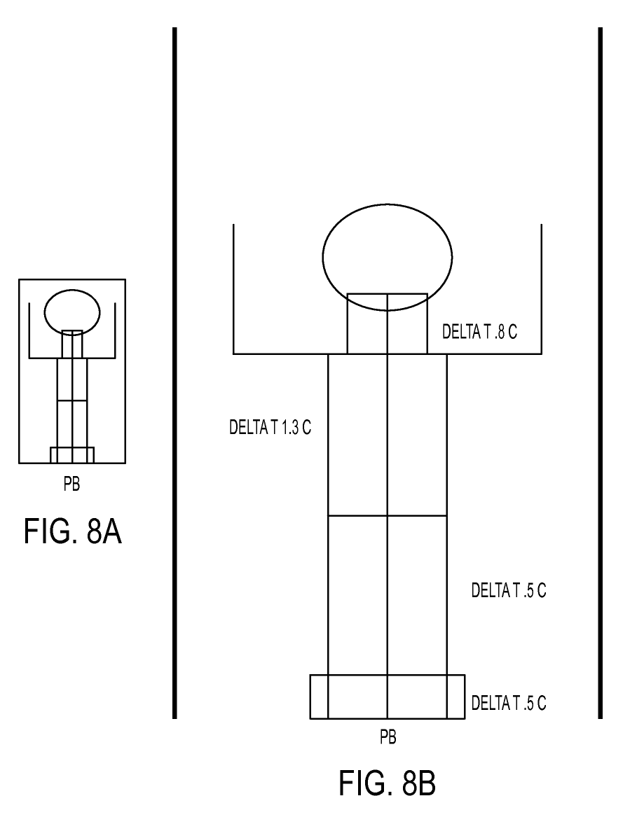

FIGS. 8A and 8B illustrate a posterior view of the human body and analysis techniques. Evaluation tools that are rectangle and/or circle can be used to computer temperature averages to determine area with highest and lowest readings. These analysis tools provide a quick capability of placing the same rectangular evaluation tool to opposite location during scanning of the patient in the same sitting position. The process can then be repeated with the patient in the standing position. The Delta T markers illustrate temperature differences between opposite sides.

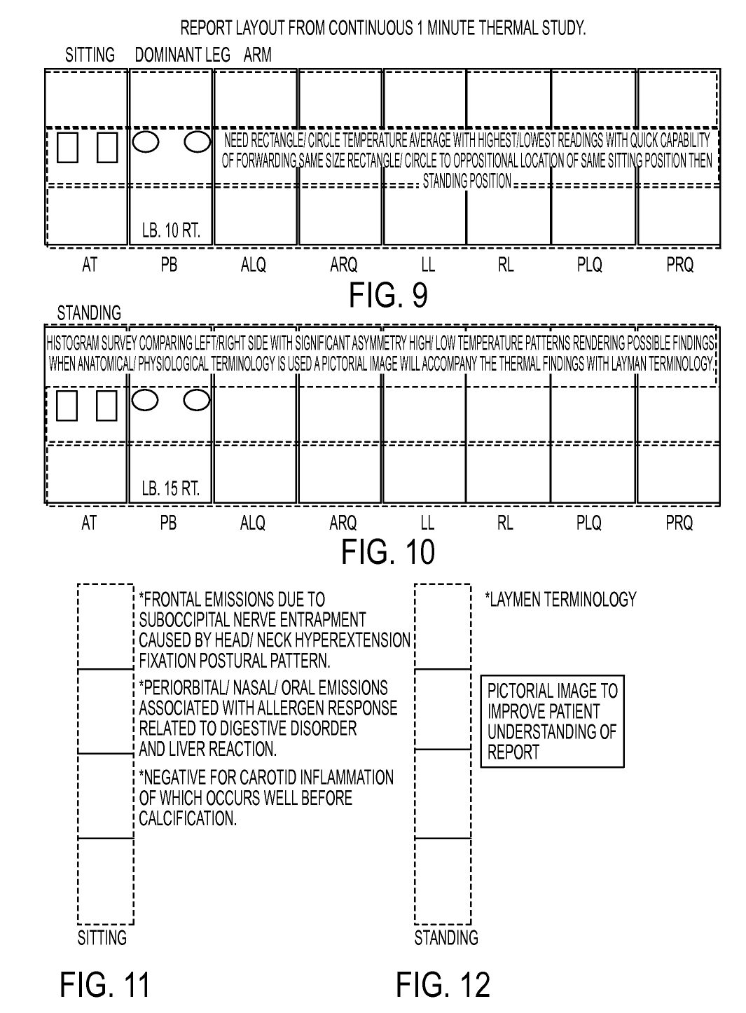

FIG. 9 is a chart used to list factors found from analysis. The chart in FIG. 9 is intended to show that rectangular and/or circular evaluative tools are used to compute temperature averages to determined areas with the highest and lowest readings and a quick capability for the same size rectangular/circular tool to be applied to the corresponding location on the opposite side of same sitting position, then repeated in a standing position.

FIG. 10 is a chart used to list factors found from analysis. The histogram survey compares the left side readings with the right side readings to determine patterns of significant asymmetry, high/low temperature patterns to render findings. A pictorial image can be generated to illustrate the results of the thermal scan and thermal image. When anatomical/physiological terminology is used a pictorial image can accompany the thermal findings with layman terminology. Pictorial images can be crate to improve patient understanding of report. Thermal images can be presented in a color coded format that clearly identifies warmer and cooler areas of the patient.

The computer will examine the scan for various issues. A number of issues can be related to vertebrae and the nerves that emanate form the nerves.

The suboccipital nerve is the first spinal nerve to exit the spinal cord between the skull and the first cervical vertebra. The suboccipital nerve sends branches to the greater and the lesser posterior rectus muscles of the head, to the superior and inferior oblique muscles of the head, to the lateral rectus muscle of the head, and to the semispinal muscle of the head. The suboccipital nerve has nerve branches that supplies muscles around the suboccipital triangle including the rectus capitis posterior major, obliquus capitis superior, and obliquus capitis inferior. Four pairs of suboccipital muscles can cause deep aching pain from the back of the head to the eye and possibly cause balance and dizziness problems. One of these (the rectus capitis superior minor) attaches directly to the dura mater of the spinal cord and if traumatized can produce visual and neurological symptoms to the point of seizures. Suboccipitals are commonly strained or hypertrophied in persons who wear bifocals, children who watch TV lying with chin propped on hands, and anyone who habitually holds the head in position with chin up and neck flexed backward.

A computer can scan the thermal image of a patient for frontal emissions due to Suboccipital Nerve entrapment that can be caused by head and/or neck hyperextension fixation postural pattern. The result of this scan is clearly seen on a display the heat emissions that occur as a result Suboccipital Nerve entrapment or other problems that occur problems with the Suboccipital Nerve.

Periorbital (around the eye socket) and/or nasal oral emissions associated with an allergen response related to digestive disorder and liver reaction can be detected by a computer scan of a thermal image.

Bilateral TM Joint disruption can result with Temporalis myofascial activity. This condition can be detected by a computer scanning a thermal image of the patient.

Periodontal (around the tooth) infection with Submandibular Lymphatic involvement.

Infections can occur in the lymph nodes structures of the upper neck. Infection can cause the lymph nodes to become enlarged and may have red swelling in the parotid or submandibular glands. The lymph nodes can also become enlarged due to tumors.

Benign and malignant tumors within salivary glands can be painless enlargements. Tumors can be are detected as a growths in either the parotid, submanidibular area, the palate, the mouth, cheeks or lips.

Parotid hypertrophy associated with hormone influence.

Negative for Carotid inflammation of which occurs well before calcification.

Bilateral Scalenus myofascitis resulting in neurovascular entrapment causing cold hands.

Parotid hypertrophy associated with digestive disorder.

T1/2 hypo-emissions suggestive of chronic immune deficiency.

Thyroid hypertrophy associated with iodine deficiency.

Maxillary/Ethmoid Sinus infection resulting in Eustachian Tube closure affecting Mastoid Sinus.

Mastoid Sinus infection due to Eustachian Tube dysfunction can resulting in equilibrium issues.

Occiput/Atlas Fixation due to hyperextension of the head! neck to counterbalance a thoracic forward distortion.

Left/right Facet Disorder resulting from vertebrae and nerve problems.

The computer can also examine the scan for various thyroid based issues.

Myofascial activity noted over the

Vertebral Fixation noted over with paravertebral myofascitis beginning at T2—Negative for Coronary Arterial disruption.

T3—Hypoemissions noted over the left chest is suggestive of Coronary autonomic distress

In those embodiments in which a patient is standing while the thermal image is taken, the scan can be examined for various lower body issues.

Pancreas dysfunction with hiatal pressure resulting in Ascending/Descending Colon inflammation.

Lower abdominal hypo-emissions are indicative of autonomic bladder dysfunction.

The computer can also be programmed to examine the scan for various spinal related based issues.

Left pelvic drop results in left anterior spinal distortion.

Right pelvic drop results in right anterior spinal distortion. with

Left pelvic drop resulting from over defensive right anterior spinal displacement.

Right pelvic drop resulting from over defensive left anterior spinal displacement.

No significant thermal asymmetry/imbalance (comparing one breast to the other so as to be specific with bodies physiology while identifying inflammation/lymphatic congestion).

Above left nipple linear emissions

Above the left nipple at :00 O'clock with linear emissions that reduces in Cold Stress Study suggestive of continued autonomic control, which pathological tissue are not.

Nipple appears to have balanced thermal emissions.

Left mild nipple asymmetrical of emissions with left auxiliary lymphatic congestion.

Auxiliary (arm pit) thermal emission balance.

No indications of neovascularity/angiogenesis, a dysfunctional capillary development

Organized vascular heat pattern to support abnormal tissue development accompanied by intense emissions due to extensive cellular death producing Nitric Oxide of which ferments to the skin surface resulting in “Hot Spots”

Findings demonstrated a low risk of developing pathology.

These images will be should be archived as a baseline study to establish your thermal thumb print to recognize changes associated with new tissue development.

Comparative study recommended in three months to establish tissue physiological stability.

Above the left nipple at :00 O'clock with linear emissions that reduces in Cold Stress Study suggestive of continued autonomic control, which pathological tissue are not.

In an embodiment, system 10 will provide a video presentation. As the patient/customer unlocks the door 13, a 10 minute instructional presentation video presentation will be triggered. The video guides the patient/customer through a detailed process in taking the Thermo Body Health Scan.

In another embodiment, an instructional video directs the customer through the entire scanning session. Typically scanning sessions would last about 10 minutes, although this can vary greatly.

In another embodiment, the patient/customer will stand and align himself at designated floor makings. Once aligned a laser light switch activates the thermo camera and begins recording video images.

In another embodiment, the patient/customer will follow instructions and rotate 360° degrees for complete video capture.

In another embodiment, the instructional video will continue until all the images in a 360° circle are completed. The patient/customer then steps away from laser which will trigger a shut down to the camera and allow the patient/customer to begin getting dressed.

In another embodiment, the patient/customer can view the images by using his credit card or other identifying number. In one specific embodiment, a Costco card number entered at a location on the internet (such as www.thermobodyscan.Com Web site) will allow the patient to view the thermal images.

In an embodiment, upon completion of the scan the images are saved a server, such as a HIPPA complied server. The server can belong to the same company that owns system 10. The images are stored under patient's/customer's membership number. Once at home, the patient/customer can be asked to complete a medical questionnaire which can be either attached or accompanying his thermo images.

In another embodiment, reading doctors will be able to sign into the server containing the thermal scan images at any time and begin reading the images. The images can be aligned with the patient's/customer's medical report.

Upon receiving customer's completed questionnaire, the server will place the customers views and information into a “Que”. Ready for reading.

A computer program can review the thermo scan in (12) specific areas to identify “Suspicious areas of Concern”. If there are none then there is no need for a Doctors review and a computer generated “Clean Scan Report” would be posted on the Thermo Body Scan Web site within minutes after the pictures were taken. (A Board certified Doctor estimated that more then half of the thermo scans would NOT need to be seen by a reading Doctor.) Thermo Body Scan Reading Doctors would only be given scans of SUSPICION or Concern” to read. Customers with a “Suspicious” scan would be able to access and read their complete report, with the reading Doctors comments, with 48 hours of the scan being taken.

### Patient/Customer Login

A patient/customer can be instructed to go home and login onto website to view images at www.thermobodyscan.com.

The patient/customer can be requested to register and create a new login. The patient/customer can enter their membership number to locate their images.

In an embodiment, the patient/customer will be re-directed to complete a medical history questionnaire.

Embodiments are envisioned in which after submitting the above questionnaire, patients will be able to see their images. Other embodiment need not require the questionnaire.

### Reports

In an embodiment, once the server 19 receives images and complete medical history questionnaire, it will upload this file to sit in queue for the next reading doctor to download and review.

A Board Certified Reading doctor will be able to write, dictate or use “Macro Medical” terms in posting his medical interpolation and findings. All areas of areas of concern can be specifically noted.

In an embodiment, doctors will be able to stop and enlarger specific areas in the thermo video images by simply moving a mouse over areas of concern. The patient/customer will be able to give his personal physician his log in password where the physician will be able to review the images and the Reading Doctors report.

The customer' will be able to give his access code to his personal physician. The computer generated report as well as the Thermo Reading Doctor's report will have specific pages, in the Medical Doctors area of the Thermo web site, which correlate to the patients report which indicate areas of concern.

An email can be automatically sent to the customers informing them that was soon as the completed report is ready.

### Reading Doctors

In an embodiment, at the end of each month, there will be an email sent to each reading doctor to confirm the number of reports completed. Upon conformation by the Reading Doctor his bank account is automatically deposited with the fees earned for the month.

### Follow-Ups

In an embodiment, an automatic email is sent to customer reminding them their annual Thermo Body Scan date is coming up. Emails will encourage customer to continue updating their baseline for updated comparative results to maintain optimum health status.

In another embodiment, a computer program will compare annual thermo scans with the ‘base Scan’ to view any changes. By comparing and identifying any changes early, the Thermo Body Scan monitoring can potentially save hundreds of thousands of lives. Early Detection greatly increases hope for an early cure.

### Programming

In an embodiment, the system 10 can utilize assigned pin point areas of detection to summarize to alert if there is a concern.

In another embodiment, the Thermo scan report can have a final “Patient Health Summary”. If the summary shows that there is an area to be concerned with, this patient's file can be immediately deposited into the queue (server) for medical doctor review. If there are no areas of concern established, an email will be immediately sent to the patient informing them of the results.

In another embodiment, a medical encyclopedia for doctors is established to refer to on the website, this can be a hidden page, but not necessarily so.

In another embodiment, system 10 is programmed to allow doctors to circle areas of concern and enter comments on the side with an arrow pointing out the disorder.

In another embodiment, system 10 is programmed to allow superimposing of an image on top of another i.e. the current year's images on top of last year's images for comparison purposes.

In another embodiment, system 10 will provide images to patients/customers once the patient/customer establishes an account and logs in.

1. A system for patient scanning and production of a thermal image comprising:
an enclosed area arranged for patient scanning having a closeable opening;
a positioning mechanism within said enclosed areas that places the patient into at least one predetermined position;
a thermal scanning device arranged to scan patients in said predetermined position and create a thermal scan of patients; and
a control device in communication with said thermal scanning device to receive data from said thermal scanning device.

2. The system of claim 1 further comprising a thermal imaging device associated with at least one of said thermal scanning device or said control device to create a thermal image of patients from at least wherein said patient scan created by said scanning device is a thermal scan.

3. The system of claim 1 wherein said positioning mechanism further comprises a chair.

4. The system of claim 3 wherein said chair further has a location device arranged to place patient into said predetermined position.

5. The system of claim 1 wherein said positioning mechanism further comprises a location device inside said enclosed area to place patient in said predetermined position.

6. A system for patient scanning and production of a thermal image comprising:
an enclosed area arranged for patient scanning having a closeable opening;
a positioning mechanism within said enclosed areas that places the patient into at least one predetermined position;
a thermal imaging device arranged to scan patients in said predetermined position and create a thermal image of patients; and
a control device in communication with said thermal imaging device to receive data from said thermal imaging device and to send control data to said thermal imaging device.

7. A method for scanning a patient to create a thermal image comprising the steps of:
providing an enclosed area arranged to scan a patient, the enclosed area having a closeable entrance that allows the patient privacy;
positioning the patient within the enclosed area such the patient is in a predetermined position;
scanning the patients with a scanner while in said predetermined position to create a thermal image of the patient; and
communicating between a computational element, the enclosed area and scanning device to provide data and control signals to the scanning device.

8. The method of claim 7 wherein the method further comprises the step of communication data for the thermal image data to a remote location.
